(19) United States
(12) Patent Application Publication
(10) Pub. No.: US 2026/0072347 A1
(43) Pub. Date: Mar. 12, 2026

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Kyoungjin HA, Suwon-si (KR); Ran NAMGUNG, Suwon-si (KR); Hyeon PARK, Suwon-si (KR); Daeseok SONG, Suwon-si (KR)

(21) Appl. No.: 19/314,837

(22) Filed: Aug. 29, 2025

(30) Foreign Application Priority Data
Sep. 6, 2024 (KR) 10-2024-0121848
Mar. 28, 2025 (KR) 10-2025-0040560

(51) Int. Cl. G03F 7/004; G03F 7/20

(52) U.S. Cl. CPC G03F 7/0043; G03F 7/2043

(57) ABSTRACT

A semiconductor photoresist composition and a method of forming patterns using the semiconductor photoresist composition are provided. The semiconductor photoresist composition includes an organometallic compound; a (meth)acrylate-based polymer including at least one selected from among metals each having a valence of 2 to 6; and a solvent.

### CROSS-REFERENCE TO RELATED APPLICATIONS

The present application claims priority to and the benefit of Korean Patent Application No. 10-2024-0121848, filed on Sep. 6, 2024, in the Korean Intellectual Property Office, and Korean Patent Application No. 10-2025-0040560, filed on Mar. 28, 2025, in the Korean Intellectual Property Office, the entire content of each of which is incorporated herein by reference.

### BACKGROUND

### 1. Field

One or more embodiments of the present disclosure relate to a semiconductor photoresist composition and a method of forming patterns using the same.

### 2. Description of the Related Art

EUV (extreme ultraviolet) lithography has drawn much attention as an essential technology for manufacturing next generation semiconductor devices (e.g., semiconductor chips). The EUV lithography is a pattern-forming technology using an EUV ray with a wavelength of 13.5 nm as an exposure light source. It is known that an extremely fine pattern (e.g., less than or equal to 20 nm) may be formed in an exposure process during the manufacture of semiconductor devices (e.g., semiconductor chips).

Extreme ultraviolet (EUV) lithography is realized through development of compatible photoresists that may be performed at a spatial resolution of less than or equal to 16 nm. Currently, efforts to alleviate insufficient specifications of chemically amplified (CA) photoresists such as a resolution, a photospeed, and feature roughness (or also referred to as a line edge roughness or LER) for next generation devices have been made.

Intrinsic image blurring due to an acid catalyzed reaction in these polymer-type (kind) photoresists limits resolution in small feature sizes, which has existed in electron beam (e-beam) lithography for a long time. Chemically amplified (CA) photoresists are designed for high sensitivity, but their typical elemental makeup reduces light absorbance of the photoresists at a wavelength of 13.5 nm, thus decreasing their sensitivity. Consequently, the chemically amplified (CA) photoresists may face more difficulties under an EUV exposure.

Additionally, CA photoresists may have difficulties with the small feature sizes due to roughness issues. Experimentally, line edge roughness (LER) of the CA photoresists increases as photospeed decreases, partially due to the nature of acid catalyst processes. Accordingly, a novel high-performance photoresist is desired or required in a semiconductor industry because of these defects and problems with CA photoresists.

To overcome the aforementioned drawbacks of chemically amplified (CA) organic photosensitive compositions, inorganic photosensitive compositions have been researched. The inorganic photosensitive composition is mainly or predominantly used for negative tone patterning, having resistance against removal by a developer composition due to chemical modification through a nonchemical amplification mechanism. Inorganic compositions contain an inorganic element with a higher EUV absorption rate than hydrocarbons, thus securing sensitivity through the nonchemical amplification mechanism. Additionally, they are less sensitive to stochastic effects and are known to have low line edge roughness and fewer defects.

Inorganic photoresists based on peroxopolyacids of tungsten mixed with tungsten, niobium, titanium, and/or tantalum have been reported as radiation sensitive materials for patterning.

These materials are effective for patterning large pitches for bilayer configuration as far ultraviolet (deep UV), X-ray, and electron beam sources. When cationic hafnium metal oxide sulfate (HfSOx) materials along with a peroxo complexing agent was used to image a 15 nm half-pitch (HP) through projection EUV exposure, improved performance has been obtained. This system exhibits a high performance of a non-CA photoresist and has a practicable photospeed near to a requirement for an EUV photoresist. However, the hafnium metal oxide sulfate material having the peroxo complexing agent has some practical drawbacks. First, these materials are coated in a mixture of corrosive sulfuric acid/hydrogen peroxide and have insufficient shelf-life stability. Second, structural changes for performance improvement as a composite mixture are challenging. Third, development should be performed in a TMAH (tetramethylammonium hydroxide) solution at an extremely high concentration of 25 wt % and/or the like.

To address these issues, research has focused on developing molecules that include tin, which have excellent or suitable absorption of extreme ultraviolet rays. For an organotin polymer among these molecules including tin, alkyl ligands are dissociated by light absorption or secondary electrons produced thereby. The dissociated alkyl ligands are then crosslinked with adjacent chains through oxo bonds, enabling negative tone patterning that may not be removed by an organic developer. Although this organotin polymer exhibits greatly improved sensitivity and maintains desired resolution and line edge roughness, the patterning characteristics need or desire further improvement for commercial availability.

### SUMMARY

One or more aspects of embodiments of the present disclosure are directed toward a semiconductor photoresist composition that has enhanced (e.g., excellent or suitable) sensitivity and LER characteristics.

One or more aspects of embodiments of the present disclosure are directed toward a method of forming patterns using the semiconductor photoresist composition.

Additional aspects will be set forth in part in the description which follows and, in part, will be apparent from the description, or may be learned by practice of the presented embodiments of the disclosure.

According to one or more embodiments of the present disclosure, a semiconductor photoresist composition includes an organometallic compound, a (meth)acrylate-based polymer including at least one selected from among metals each having a valence of 2 to 6, and a solvent.

According to one or more embodiments of the present disclosure, a method of forming patterns includes forming an etching-objective layer (e.g., etching-target layer) on a substrate, coating the semiconductor photoresist composition on the etching-objective layer to form a photoresist film, patterning the photoresist film to form a photoresist pattern, and etching the etching-objective layer using the photoresist pattern as an etching mask.

A pattern formed using the semiconductor photoresist composition according to one or more embodiments may have excellent or suitable sensitivity and LER characteristics. For example, the development of semiconductor photoresist compositions that incorporate organometallic compounds and (meth)acrylate-based polymers represents an advancement in the field of EUV lithography. These compositions not only address the limitations of traditional CA photoresists but also offer improved sensitivity and reduced line edge roughness, which are for achieving high-resolution patterns. By leveraging the unique properties of metals with valences of 2 to 6, the photoresists of the present disclosure enhance the absorption of EUV rays, thereby increasing the efficiency of the patterning process. Furthermore, the method of forming patterns using the compositions of the present disclosure ensures that the etching-objective layer is precisely etched, resulting in highly accurate and reliable semiconductor devices. This photoresist technology is to meet the demands of next-generation semiconductor manufacturing, paving the way for more sophisticated and miniaturized electronic components.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIGS. 1A-1E are cross-sectional views for illustrating a method of forming patterns using a semiconductor photoresist composition according to one or more embodiments of the present disclosure.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

Hereinafter, referring to the drawings, one or more embodiments of the present disclosure will be described in more detail. In the following description of the disclosure, the well-established functions or constructions will not be described in order to make the present disclosure concise.

To clearly illustrate the present disclosure, certain unessential description and relationships are omitted, and throughout the disclosure, the same or similar configuration elements are designated by the same reference numerals. Also, because the size and thickness of each configuration shown in the drawing are shown for better understanding and ease of description, the present disclosure is not necessarily limited thereto.

In the drawings, the thickness of layers, films, panels, regions, and/or the like, may be exaggerated for clarity. In the drawings, the thickness of a part of layers or regions, and/or the like, may be exaggerated for convenience of explanation. It will be understood that if (e.g., when) an element such as a layer, film, region, or substrate is referred to as being “on” another element, it may be directly on the other element or one or more intervening elements may also be present therebetween. In contrast, when an element is referred to as being “directly on” another element, there are no intervening elements present.

As used herein, “substituted” refers to replacement of a hydrogen by deuterium, a halogen, a hydroxyl group, a carboxyl group, a thiol group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, and/or a (e.g., any suitable) combination thereof. “Unsubstituted” refers to non-replacement of a hydrogen by another substituent and remaining of the hydrogen.

As used herein, if (e.g., when) a definition is not otherwise provided, the term “alkyl group” refers to a linear or branched aliphatic hydrocarbon group. The alkyl group may be a “saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, the term “cycloalkyl group” refers to a monovalent cyclic aliphatic hydrocarbon group.

The cycloalkyl group may be a C3 to C8 cycloalkyl group, for example, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but embodiments of the present disclosure are not limited thereto.

As used herein, the term “aliphatic unsaturated organic group” refers to a hydrocarbon group including a bond in which the bond between carbon and carbon atoms in a molecule is a double bond, a triple bond, or a (e.g., any suitable) combination thereof.

The aliphatic unsaturated organic group may be a C2 to C8 aliphatic unsaturated organic group. For example, the aliphatic unsaturated organic group may be a C2 to C7 aliphatic unsaturated organic group, a C2 to C6 aliphatic unsaturated organic group, a C2 to C5 aliphatic unsaturated organic group, or a C2 to C4 aliphatic unsaturated organic group. For example, the C2 to C4 aliphatic unsaturated organic group may be a vinyl group, an ethynyl group, an allyl group, a 1-propenyl group, a 1-methyl-1-propenyl group, a 2-propenyl group, a 2-methyl-2-propenyl group, a 1-propynyl group, a 1-methyl-1 propynyl group, a 2-propynyl group, a 2-methyl-2-propynyl group, a 1-butenyl group, a 2-butenyl group, a 3-butenyl group, a 1-butynyl group, a 2-butynyl group, or a 3-butynyl group.

As used herein, the term “aryl group” refers to a substituent in which all atoms in the cyclic substituent have a p-orbital and these p-orbitals are conjugated and may include a monocyclic or fused ring polycyclic functional group (i.e., rings sharing adjacent pairs of carbon atoms).

As used herein, the term “heteroaryl group” may refer to an aryl group including at least one heteroatom selected from among N, O, S, P, and Si. Two or more heteroaryl groups may be linked by a sigma bond directly, or if (e.g., when) the heteroaryl group includes two or more rings, the two or more rings may be fused. When the heteroaryl group is a fused ring, one or more rings may include one to three heteroatoms.

As used herein, unless otherwise defined, the term “alkenyl group” refers to a linear or branched aliphatic hydrocarbon group including at least one double bond as an aliphatic unsaturated alkenyl group.

As used herein, unless otherwise defined, the term “alkynyl group” refers to a linear or branched aliphatic hydrocarbon group including at least one triple bond as an aliphatic unsaturated alkynyl group.

As used herein, “(meth)acrylic” refers to “acrylic” and/or “methacrylic,” and “(meth)acrylate” refers to “acrylate” and/or “methacrylate.”

Hereinafter, a semiconductor photoresist composition according to one or more embodiments will be described.

A semiconductor photoresist composition according to one or more embodiments includes: an organometallic compound; a (meth)acrylate-based polymer including at least one selected from among metals each having a valence of 2 to 6; and a solvent.

The (meth)acrylate-based polymer included in the semiconductor photoresist composition may improve sensitivity and LER by introducing a metal element having a high EUV absorption rate into the polymer, thereby reducing photon shot noise of the photoresist pattern.

For example, in one or more embodiments, the (meth)acrylate-based polymer may include at least one selected from among a structural unit derived from a monomer represented by Chemical Formula 1 and a structural unit derived from a monomer represented by Chemical Formula 2.

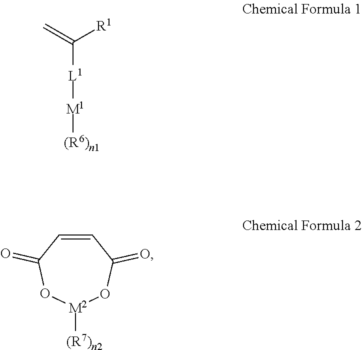

In Chemical Formula 1 and Chemical Formula 2,
R¹ may be hydrogen or a substituted or unsubstituted C1 to C10 alkyl group,
M¹ and M² may each independently be a metal having a valence of 2 to 6,
L¹ may be a single bond, —C(O)O—, a substituted or unsubstituted C1 to C10 alkylene group, a substituted or unsubstituted C6 to C20 arylene group, or a (e.g., any suitable) combination thereof,
R⁶ and R⁷ may each independently be a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C6 to C20 aryl group, OR^{b}, or OC(═O)R^{c} (wherein, R^{b} and R^{c} may each independently be a substituted or unsubstituted C1 to C10 alkyl group),
n1 may be an integer from 1 to 5,
n2 may be an integer from 0 to 4, and
if (e.g., when) n1 and n2 are each 2 or greater, two or more selected from among respective R⁶(s) and R⁷(s) may independently be the same as or different from each other.

For example, in one or more embodiments, M¹ may be Sn, Sb, or Te, and n1 may be an integer from 1 to 3.

For example, in one or more embodiments, M² may be Sn or Sb, and n2 may be an integer of 1 or 2.

In one or more embodiments, M¹ and M² may each be Sn, n1 may be an integer of 3, and n2 may be an integer of 2.

For example, in one or more embodiments, the monomer represented by Chemical Formula 1 and the monomer represented by Chemical Formula 2 may each be selected from among monomers listed in Group I.

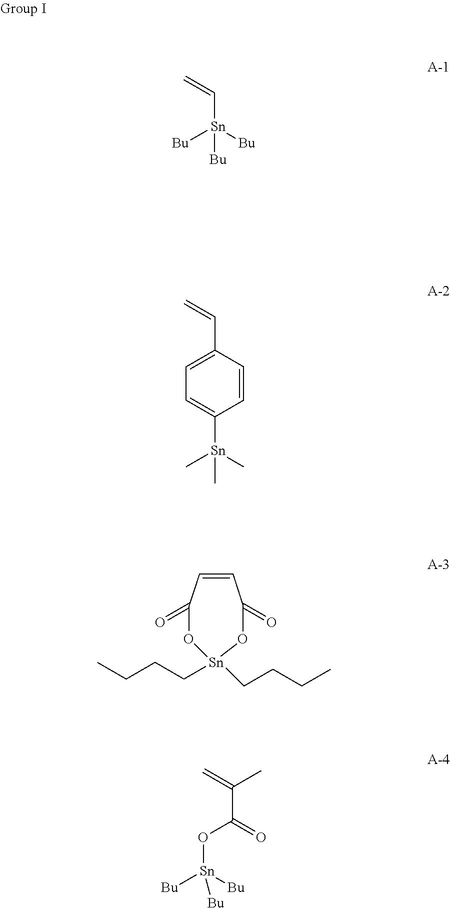

In one or more embodiments, the (meth)acrylate-based polymer may include about 50 to about 100 mol % of at least one selected from among the structural unit derived from the monomer represented by Chemical Formula 1 and the structural unit derived from the monomer represented by Chemical Formula 2.

In one or more embodiments, the (meth)acrylate-based polymer may further include a structural unit derived from a monomer including an ethylenically unsaturated group.

The “monomer including an ethylenically unsaturated group” refers to a molecule having one or more carbon-carbon double bonds and capable of insertion addition polymerization.

The monomer including the ethylenically unsaturated group may be, for example, an alkyl (meth)acrylate monomer; or a (meth)acrylate monomer including one or more functional groups selected from among a hydroxyl group, an amino group, a carboxyl group, a sulfonamide group, a hexafluoroisopropyl alcohol group [—C(CF₃)₂OH], an anhydride, a lactone group, an ester group, an ether group, an allylamine group, a pyrrolidone group, and/or a (e.g., any suitable) combination thereof.

The alkyl (meth)acrylate monomer may be, for example, at least one selected from among methyl (meth)acrylate, ethyl (meth)acrylate, propyl (meth)acrylate, isopropyl (meth)acrylate, butyl (meth)acrylate, pentyl (meth)acrylate, hexyl (meth)acrylate, heptyl (meth)acrylate, octyl (meth)acrylate, isooctyl (meth)acrylate, 2-ethylhexyl (meth)acrylate, decyl (meth)acrylate, isodecyl (meth)acrylate, dodecyl (meth)acrylate, isobornyl (meth)acrylate, lauryl (meth)acrylate, and/or a (e.g., any suitable) mixture thereof.

The hydroxyl group-containing (meth)acrylate monomer may be, for example, at least one selected from among 2-hydroxyethyl (meth)acrylate, 2-hydroxypropyl (meth)acrylate, 2-hydroxybutyl (meth)acrylate, 4-hydroxybutyl (meth)acrylate, 6-hydroxyhexyl (meth)acrylate, 1,4-cyclohexanedimethanol mono(meth)acrylate, 1-chloro-2-hydroxypropyl (meth)acrylate, diethylene glycol mono(meth)acrylate, 1,6-hexanediol mono(meth)acrylate, pentaerythritol tri(meth)acrylate, dipentaerythritol penta(meth)acrylate, neopentylglycol mono(meth)acrylate, trimethylolpropane di(meth)acrylate, trimethylolethane di(meth)acrylate, 2-hydroxy-3-phenyloxypropyl (meth)acrylate, 4-hydroxycyclopentyl (meth)acrylate, 4-hydroxycyclohexyl (meth)acrylate, cyclohexanedimethanol mono(meth)acrylate, and/or a (e.g., any suitable) mixture thereof.

The amino group-containing (meth)acrylate monomer may be, for example, at least one selected from among N,N-dimethylaminoethyl (meth)acrylate, N,N-diethylaminoethyl (meth)acrylate, N,N-dibutylaminoethyl (meth)acrylate, 2-(2-dimethylaminoethyl(methyl)amino)ethyl (meth)acrylate, 2-(2-dimethylaminoethyloxy)ethyl (meth)acrylate, 2-(diisopropylamino)ethyl (meth)acrylate, 2-morpholinoethyl (meth)acrylate, 2-(1-piperidyl)ethyl (meth)acrylate, 2-(N-ethylanilino)ethyl (meth)acrylate, 2-imidazol-1-ylethyl (meth)acrylate, N,N-dimethylaminopropyl (meth)acrylate, N,N-dimethylaminoethyl (meth)acrylamide, and/or a (e.g., any suitable) mixture thereof.

The (meth)acrylate-based polymer may be a homopolymer or a copolymer having a plurality of different structural units, for example, two, three, four or more different structural units.

In one or more embodiments, the (meth)acrylate-based polymer may be any one selected from among polymers listed in Group 1.

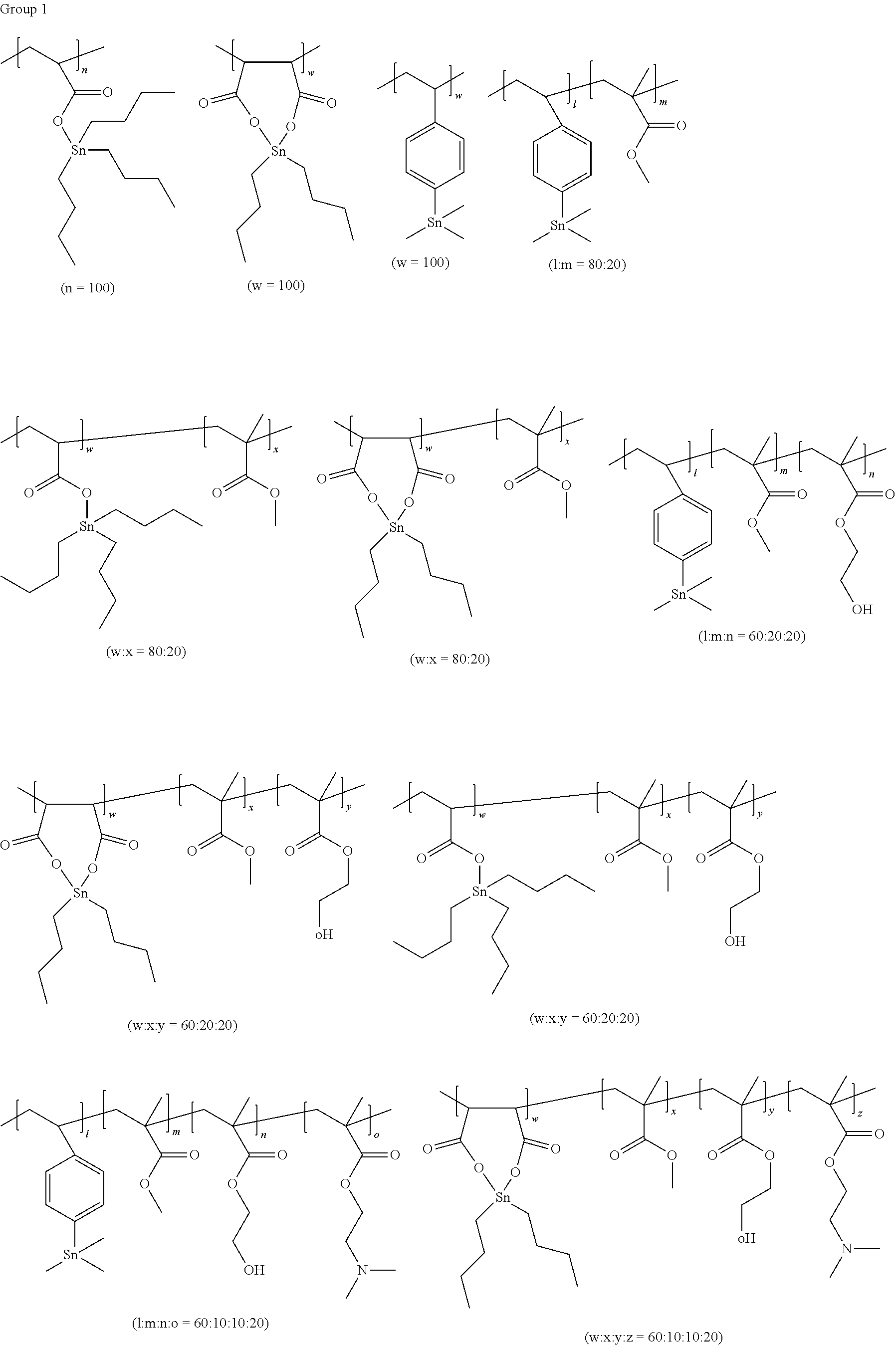

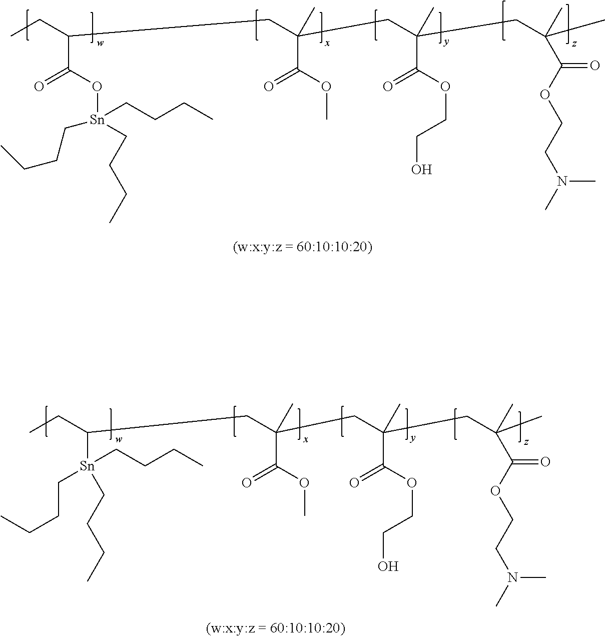

In group 1, l, m, n, w, x, y, and z each represent mol %.

The (meth)acrylate-based polymer may be included in an amount of about 0.001 to about 10 wt % based on 100 wt % of a total weight of the semiconductor photoresist composition.

For example, in one or more embodiments, the (meth)acrylate-based polymer may be included in an amount of about 0.01 to about 10 wt %, about 0.01 to about 5 wt %, about 0.05 to about 5 wt %, or about 0.1 to about 5 wt % based on 100 wt % of the total weight of the semiconductor photoresist composition.

The organometallic compound may be included in an amount of about 0.5 wt % to about 30 wt % based on 100 wt % of the total weight of the semiconductor photoresist composition.

The semiconductor photoresist composition according to one or more embodiments may improve the sensitivity of the photoresist by including the organometallic compound and the (meth)acrylate-based polymer within the above amount ranges.

The semiconductor photoresist composition according to one or more embodiments may include the organometallic compound: the (meth)acrylate-based polymer in a weight ratio of about 99:1 to about 60:40. For example, in one or more embodiments, the semiconductor photoresist composition may include the organometallic compound: the (meth)acrylate-based polymer in a weight ratio of about 90:10 to about 60:40.

When the weight ratio of the organometallic compound to the aforementioned (meth)acrylate-based polymer satisfies the above range, the semiconductor photoresist composition having excellent or suitable sensitivity may be provided.

The organometallic compound may be an organotin compound including at least one of an organic oxy group or an organic carbonyloxy group.

In one or more embodiments, the organometallic compound may be represented by Chemical Formula 3.

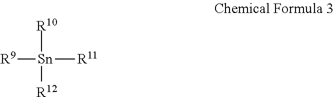

In Chemical Formula 3,
R⁹ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C6 to C30 arylalkyl group,
R¹⁰ to R¹² may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an alkylamido or dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an amidato group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an amidinato group (—NR^{h}C(NRⁱ)R^{j}, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an alkylthio or arylthio group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), or a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof),
at least one selected from among R¹⁰ to R¹² may be selected from among an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an alkylamido or dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an amidato group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an amidinato group (—NR^{h}C(NRⁱ)R^{j}, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an alkylthio or arylthio group (—SR^{k}, wherein R^{k} may be a substituted or unsubstituted C1 to C20 alkyl group, a C2 to C20 alkenyl group, a substituted or unsubstituted C2 to C20 alkynyl group, a substituted or unsubstituted C6 to C30 aryl group, or a (e.g., any suitable) combination thereof), and a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof).

In one or more embodiments, at least one selected from among R¹⁰ to R¹² may be selected from among an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), and a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof).

In one or more embodiments, because the organometallic compound represented by Chemical Formula 3 includes —OR^{b} or —OC(═O)R^{c} as a ligand, a pattern formed using a semiconductor photoresist composition including the organometallic compound may exhibit excellent or suitable limit resolution.

In addition, the ligand of —OR^{b} or —OC(═O)R^{c} may determine the solubility of the organometallic compound represented by Chemical Formula 3 in a solvent.

In one or more embodiments, R⁹ may be a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds or triple bonds, a substituted or unsubstituted C6 to C20 aryl group, a substituted or unsubstituted C4 to C20 heteroaryl group, a carbonyl group, an ethoxy group, a propoxy group, or a (e.g., any suitable) combination thereof,
R^{b} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a (e.g., any suitable) combination thereof, and
R^{c} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a (e.g., any suitable) combination thereof.

In one or more embodiments, R⁹ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a (e.g., any suitable) combination thereof,
R^{b} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a (e.g., any suitable) combination thereof, and
R^{c} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a (e.g., any suitable) combination thereof.

In one or more embodiments, the Sn-containing organometallic compound may be represented by Chemical Formula 4 or Chemical Formula 5.

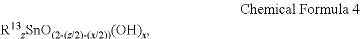

In Chemical Formula 4,
R¹³ may be a C1 to C31 hydrocarbyl group, 0<z≤2, and 0<(z+x)≤4;

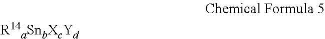

wherein, in Chemical Formula 5,
R¹⁴ may be a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a (e.g., any suitable) combination thereof,
X may be sulfur (S), selenium (Se), or tellurium (Te),
Y may be —OR^{m} or —OC(═O)Rⁿ,
wherein R^{m} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof, and
Rⁿ may be hydrogen, a substituted or unsubstituted C1 to C20 alkyl group, a C2 to C20 alkenyl group, a substituted or unsubstituted C2 to C20 alkynyl group, a substituted or unsubstituted C6 to C30 aryl group, or a (e.g., any suitable) combination thereof, and
a, b, c, and d may each independently be an integer of 1 to 20.

The solvent included in the semiconductor photoresist composition according to one or more embodiments may be an organic solvent, and may be, for example, selected from among aromatic compounds (e.g., xylene, toluene, and/or the like), alcohols (e.g., 4-methyl-2-pentanol, 4-methyl-2-propanol, 1-butanol, methanol, isopropyl alcohol, 1-propanol), ethers (e.g., anisole, tetrahydrofuran), esters (n-butyl acetate, propylene glycol monomethyl ether acetate, ethyl acetate, ethyl lactate), ketones (e.g., methyl ethyl ketone, 2-heptanone), and/or one or more (e.g., any suitable) mixtures thereof, but embodiments of the present disclosure are not limited thereto.

The semiconductor photoresist composition according to one or more embodiments may further include a resin in addition to the aforementioned organometallic compound, (meth)acrylate-based polymer, and solvent.

The resin may be a phenol-based resin including at least one aromatic moiety selected from moieties listed in Group 2.

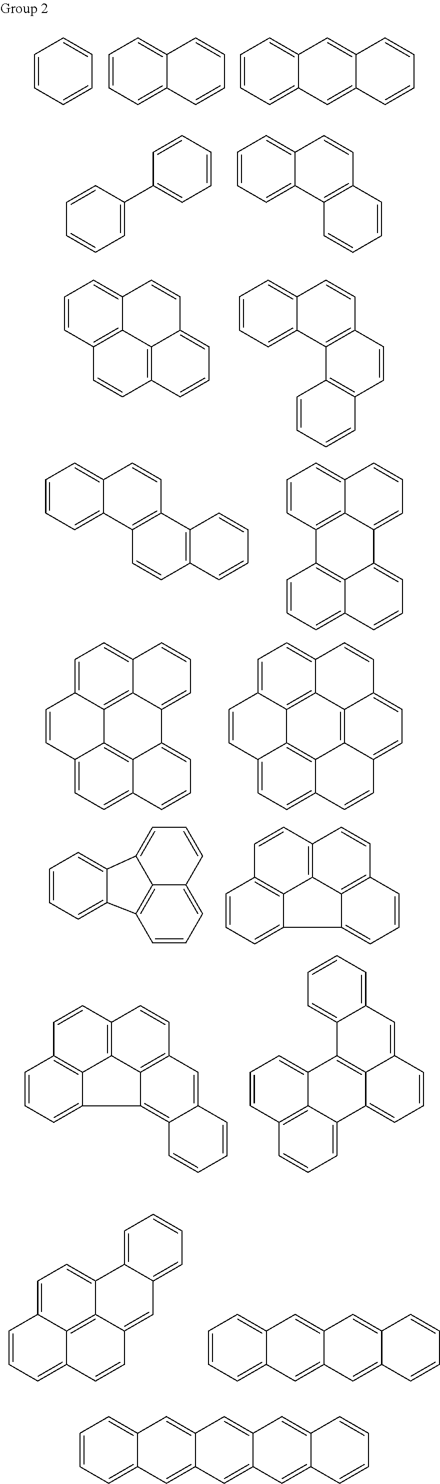

The resin may have a weight average molecular weight of about 500 to about 20,000.

The resin may be included in an amount of about 0.1 wt % to about 50 wt % based on a total weight of 100 wt % of the semiconductor photoresist composition.

If (e.g., when) the resin is included in the above amount range, it may have excellent or suitable etch resistance and heat resistance.

In addition, the semiconductor photoresist composition according to one or more embodiments may be composed of the aforementioned organometallic compound, (meth)acrylate-based polymer, solvent, and resin.

The semiconductor photoresist composition according to one or more embodiments may further include one or more additives as needed. Non-limiting examples of the additives may be a surfactant, a crosslinking agent, a leveling agent, an organic acid, a quencher, and/or a (e.g., any suitable) combination thereof.

The surfactant may include, for example, an alkyl benzene sulfonate salt, an alkyl pyridinium salt, polyethylene glycol, a quaternary ammonium salt, and/or a (e.g., any suitable) combination thereof, but embodiments of the present disclosure are not limited thereto.

The crosslinking agent may be, for example, a melamine-based crosslinking agent, a substituted urea-based crosslinking agent, an acryl-based crosslinking agent, an epoxy-based crosslinking agent, or a polymer-based crosslinking agent, but embodiments of the present disclosure are not limited thereto. In one or more embodiments, it may be a crosslinking agent having at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be used for improving coating flatness during printing and may be a commercially available suitable leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, and/or a (e.g., any suitable) combination thereof, but embodiments of the present disclosure are not limited thereto.

The quencher may be diphenyl (p-tolyl) amine, methyl diphenyl amine, triphenyl amine, phenylenediamine, naphthylamine, diaminonaphthalene, or a (e.g., any suitable) combination thereof.

An amount of the additives included in the semiconductor photoresist composition may be controlled or selected depending on desired or suitable properties.

In one or more embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be, for example, a silane compound including a carbon-carbon unsaturated bond such as vinyltrimethoxysilane, vinyl triethoxysilane, vinyl trichlorosilane, vinyl tris(β-methoxyethoxy)silane; or 3-methacryloxypropyltrimethoxysilane, 3-acryloxypropyltrimethoxysilane, p-styryl trimethoxysilane, 3-methacryloxypropylmethyldimethoxysilane, or 3-methacryloxypropylmethyl diethoxysilane; trimethoxy [3-(phenylamino)propyl]silane, and/or the like, but embodiments of the present disclosure are not limited thereto.

The semiconductor photoresist composition may be formed into a pattern having a high aspect ratio without a collapse. Accordingly, in order to form a fine pattern having a width (e.g., line width) of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, or for example, about 5 nm to about 20 nm, the semiconductor photoresist composition may be used for a photoresist process using light in a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to one or more embodiments may be used to realize extreme ultraviolet lithography using an EUV light source of a wavelength of about 13.5 nm.

According to one or more embodiments, a method of forming patterns using the aforementioned semiconductor photoresist composition is provided. For example, the manufactured pattern may be a photoresist pattern.

The method of forming patterns according to one or more embodiments includes forming an etching-objective layer (e.g., etching-target layer) on a substrate, coating the semiconductor photoresist composition on the etching-objective layer to form a photoresist film, patterning the photoresist film to form a photoresist pattern, and etching the etching-objective layer using the photoresist pattern as an etching mask.

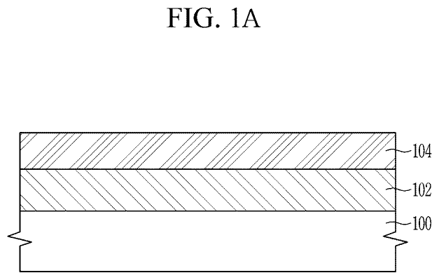

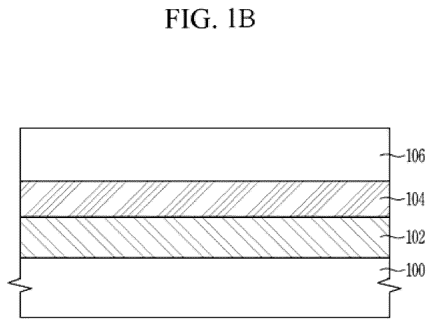

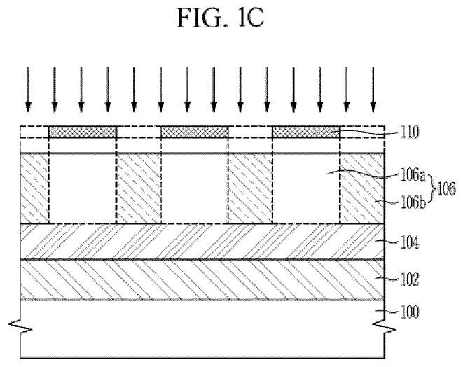

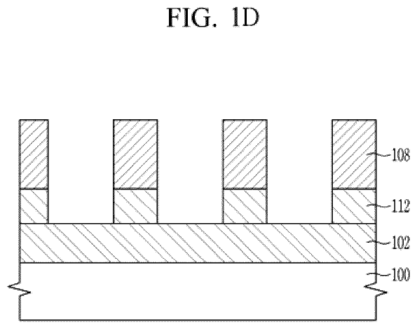

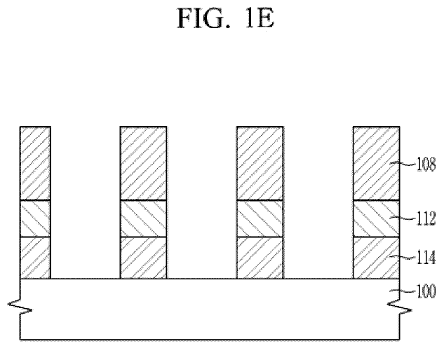

Hereinafter, a method of forming patterns using the semiconductor photoresist composition will be described in more detail by referring to FIGS. 1A-1E. FIGS. 1A-1E are cross-sectional views for illustrating a method of forming patterns using a semiconductor photoresist composition according to one or more embodiments.

Referring to FIG. 1A, an object for etching (e.g., etching-objective layer or etching-target layer) is prepared. The object for etching may be a thin film 102 formed on a semiconductor substrate 100. Hereinafter, the object for etching is limited to the thin film 102. A surface of the thin film 102 is washed to remove impurities and/or the like remaining thereon. The thin film 102 may be, for example, a silicon nitride layer, a polysilicon layer, or a silicon oxide layer.

Subsequently, a resist underlayer composition for forming a resist underlayer 104 is spin-coated on the surface of the washed thin film 102. However, embodiments of the present disclosure are not limited thereto, and various coating methods, for example, a spray coating, a dip coating, a knife edge coating, a printing method (for example an inkjet printing and/or a screen printing), and/or the like may be used.

In one or more embodiments, the coating process of the resist underlayer may not be provided, but hereinafter, a process including a coating of the resist underlayer is described.

Then, the coated resist underlayer composition is dried and baked to form the resist underlayer 104 on the thin film 102. The baking may be performed at about 100° C. to about 500° C., for example, about 100° C. to about 300° C.

The resist underlayer 104 is formed between the substrate 100 and a photoresist film 106 and thus may prevent or reduce non-uniformity of pattern formability of a photoresist line width if (e.g., when) a ray reflected from on the interface between the substrate 100 and the photoresist film 106 or a hardmask between layers is scattered into an unintended photoresist region.

Referring to FIG. 1B, the photoresist film 106 is formed by coating the semiconductor photoresist composition on the resist underlayer 104. The photoresist film 106 is obtained by coating the aforementioned semiconductor photoresist composition on the thin film 102 formed on the substrate 100 and then, curing it through a heat treatment.

In one or more embodiments, the formation of a pattern by using the semiconductor photoresist composition may include coating the semiconductor photoresist composition on the substrate 100 having the thin film 102 through spin coating, slit coating, inkjet printing, and/or the like and then, drying it to form the photoresist film 106.

The semiconductor photoresist composition has already been illustrated in more detail and will not be illustrated again.

Subsequently, the substrate 100 having the photoresist film 106 is subjected to a first baking process. The first baking process may be performed at about 80° C. to about 120° C.

Referring to FIG. 1C, the photoresist film 106 may be selectively exposed using a patterned mask 110.

For example, the exposure may use an activation radiation with light having a high energy wavelength such as EUV (extreme ultraviolet; a wavelength of about 13.5 nm), an E-Beam (an electron beam), and/or the like as well as light with short wavelengths such as an i-line (a wavelength of about 365 nm), a KrF excimer laser (a wavelength of about 248 nm), an ArF excimer laser (a wavelength of about 193 nm), and/or the like.

In one or more embodiments, light or exposure beam for the exposure according to one or more embodiments may be short-wavelength light having a wavelength in a range of about 5 nm to about 150 nm and/or a high energy wavelength, for example, EUV (extreme ultraviolet; a wavelength of 13.5 nm), and/or may be an E-Beam (an electron beam), and/or the like.

The exposed region 106b of the photoresist film 106 has a different solubility from the unexposed region 106a of the photoresist film 106 by forming a polymer by a crosslinking reaction such as condensation between organometallic compounds.

Subsequently, the substrate 100 is subjected to a second baking process. The second baking process may be performed at a temperature of about 90° C. to about 200° C. The exposed region 106b of the photoresist film 106 becomes indissoluble regarding a developer due to the second baking process.

In FIG. 1D, the unexposed region 106a of the photoresist film is dissolved and removed using the developer to form a photoresist pattern 108. For example, the unexposed region 106a of the photoresist film is dissolved and removed by using an organic solvent such as 2-heptanone and/or the like to complete the photoresist pattern 108 corresponding to a negative tone image.

As described above, a developer used in a method of forming patterns according to one or more embodiments may be an organic solvent. The organic solvent used in the method of forming patterns according to one or more embodiments may be, for example, a ketone such as methylethylketone, acetone, cyclohexanone, 2-heptanone, and/or the like, an alcohol such as 4-methyl-2-propanol, 1-butanol, isopropanol, 1-propanol, methanol, and/or the like, an ester such as propylene glycol monomethyl ether acetate, ethyl acetate, ethyl lactate, n-butyl acetate, butyrolactone, and/or the like, an aromatic compound such as benzene, xylene, toluene, and/or the like, or a (e.g., any suitable) combination thereof.

However, the photoresist pattern according to one or more embodiments is not necessarily limited to the negative tone image but may be formed to have a positive tone image. Here, a developer used for forming the positive tone image may be a quaternary ammonium hydroxide composition such as tetraethylammonium hydroxide, tetrapropylammonium hydroxide, tetrabutylammonium hydroxide, or a (e.g., any suitable) combination thereof.

As described above, exposure to light having a high energy such as EUV (extreme ultraViolet; a wavelength of 13.5 nm), to an E-Beam (an electron beam), and/or the like and/or to light having a wavelength such as i-line (wavelength of about 365 nm), KrF excimer laser (wavelength of about 248 nm), ArF excimer laser (wavelength of about 193 nm), and/or the like may provide a photoresist pattern 108 having a width of a thickness of about 5 nm to about 100 nm. For example, in one or more embodiments, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In one or more embodiments, the photoresist pattern 108 may have a pitch (center-to-center distance between adjacent features in the pattern) having (with) a half-pitch of less than or equal to about 50 nm, for example less than or equal to about 40 nm, for example less than or equal to about 30 nm, for example less than or equal to about 20 nm, or for example less than or equal to about 15 nm, and a line width roughness of less than or equal to about 10 nm, less than or equal to about 5 nm, less than or equal to about 3 nm, or less than or equal to about 2 nm.

Subsequently, the photoresist pattern 108 is used as an etching mask to etch the resist underlayer 104. Through this etching process, an organic film pattern 112 is formed. The organic film pattern 112 may also have a width corresponding to that of the photoresist pattern 108.

Referring to FIG. 1E, the exposed thin film 102 is etched by applying the photoresist pattern 108 as an etching mask. As a result, the thin film is formed as a thin film pattern 114.

In the exposure process, the thin film pattern 114 formed by using the photoresist pattern 108 formed through the exposure process performed by using an EUV light source may have a width corresponding to that of the photoresist pattern 108. For example, in one or more embodiments, the thin film pattern 114 may have a width (e.g., line width) of about 5 nm to about 100 nm which is equal to that of the photoresist pattern 108. For example, in one or more embodiments, the thin film pattern 114 formed by using the photoresist pattern 108 formed through the exposure process performed by using an EUV light source may have a width (e.g., line width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, for example, a width (e.g., line width) of less than or equal to about 20 nm, like that of the photoresist pattern 108.

Hereinafter, the present disclosure will be described in more detail through examples of the preparation of the aforementioned semiconductor photoresist composition. However, the disclosure is technically not restricted by the following examples.

### Synthesis of Organometallic Compounds

### Synthesis Example 1

40.7 g of t-butylSnPh₃ and 300 g of propionic acid were added to a 250 ml two-necked round-bottom flask and heated under reflux for 24 hours.

Unreacted propionic acid was removed under reduced pressure to obtain a compound represented by Chemical Formula 5a.

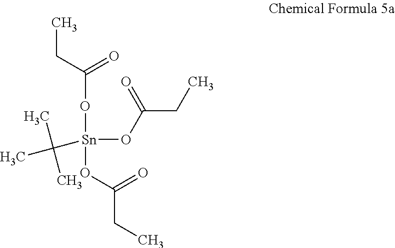 [SMILES: CCC(=O)[O][Sn]([O]C(=O)CC)([O]C(=O)CC)[C](C)(C)C]

### Synthesis Example 2

30 mL of anhydrous pentane was added to 10 g of t-AmylSnCl₃, the temperature was maintained at 0° C., and then 7.4 g of diethylamine and 6.1 g of ethanol were added thereto, and stirred at room temperature for 1 hour. When the reaction was completed, the resultant was filtered, concentrated and vacuum-dried to obtain a compound represented by Chemical Formula 6.

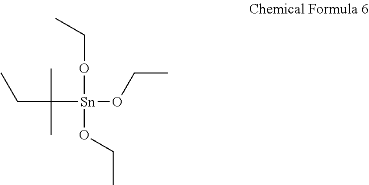

### Synthesis Example 3

10 g of dibutyltin dichloride was dissolved in 30 mL of ether, 70 mL of a 1 M sodium hydroxide (NaOH) aqueous solution was added thereto and then, stirred for 1 hour. After the stirring, a solid produced therein was filtered, three times washed with 25 mL of deionized water, and dried at 100° C. under a reduced pressure to obtain an organometallic compound represented by Chemical Formula 7 and having a weight average molecular weight of 1,500.

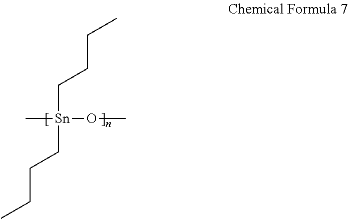

### Synthesis of (Meth)acrylate-Based Polymers

### Synthesis Example 4

20.82 g of dibutyltin maleate (TCI), 1.00 g of methyl methacrylate (Samchun Chemicals), 1.30 g of hydroxy ethyl methacrylate (LG Chem), 3.14 g of dimethyl aminoethyl methacrylate (Sigma-Aldrich Co., Ltd.), and 132.70 g of diisoamyl ether (DIAE) were added to a 250 mL 2-neck round bottom flask under a nitrogen atmosphere and then, heated to an internal temperature of 115° C.

When the internal temperature reached 115° C., 20.72 g of a 33 wt % V-601/DIAE solution (V-601, i.e., dimethyl 2,2′-azobis(2-methylpropionate)) was quantitatively added thereto over 10 minutes, and after 6 hours, the reaction solution was cooled to room temperature (25° C.), and the reaction mixture therefrom was concentrated to 50% of a solid content (e.g., amount). After adding about 270 g of heptane to the concentrated solution, a polymer produced therein was filtered. The filtered polymer was completely dissolved in 34 g of DIAE and then, precipitated by adding 270 g of heptane thereto, which was repeated twice and then, completely dried, finally obtaining Copolymer R1 (Mw=5,000).

Hereinafter, w, x, y, and z each represent mol %.

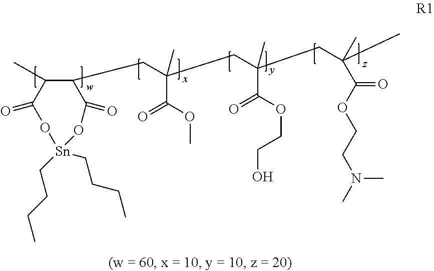

### Synthesis Example 5

Copolymer R2 (Mw=5,000) was obtained in substantially the same manner as in Synthesis Example 4 except that 16.02 g of trimethyltin styrene (TCI) was used instead of the dibutyltin maleate.

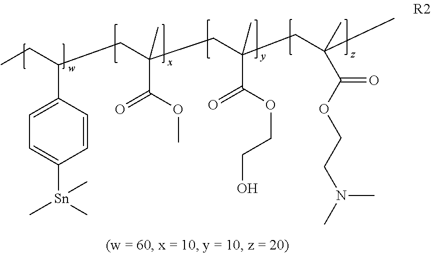

### Synthesis Example 6

Copolymer R3 (Mw=5,000) was obtained in substantially the same manner as in Synthesis Example 4 except that 22.51 g of tributyltin methacrylate (TCI) was used instead of the dibutyltin maleate.

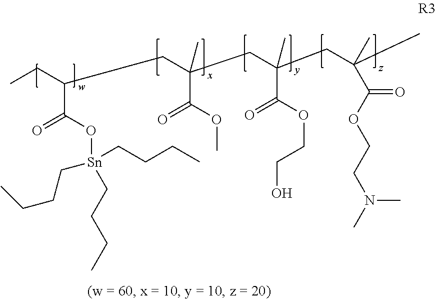

### Synthesis Example 7

Copolymer R4 (Mw=5,000) was obtained in substantially the same manner as in Synthesis Example 4 except that 22.27 g of tributyltin vinyl (TCI) was used instead of the dibutyltin maleate.

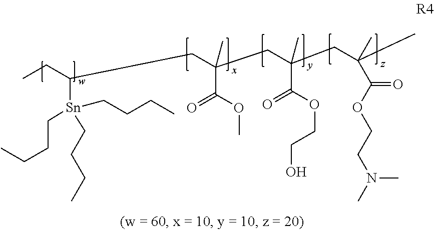

### Synthesis Example 8

Copolymer R5 (Mw=5,000) was obtained in substantially the same manner as in Synthesis Example 4 except that the dimethyl aminoethyl methacrylate was not used.

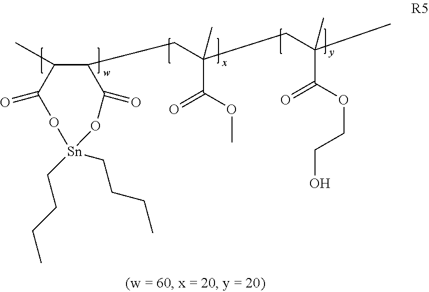

### Synthesis Example 9

Copolymer R6 (Mw=5,000) was obtained in substantially the same manner as in Synthesis Example 5 except that the dimethyl aminoethyl methacrylate was not used.

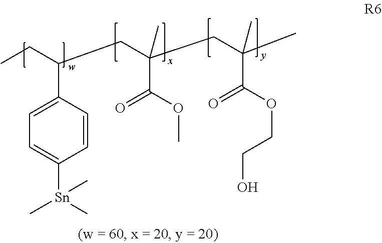

### Synthesis Example 10

Copolymer R7 (Mw=5,000) was obtained in substantially the same manner as in Synthesis Example 6 except that the dimethyl aminoethyl methacrylate was not used.

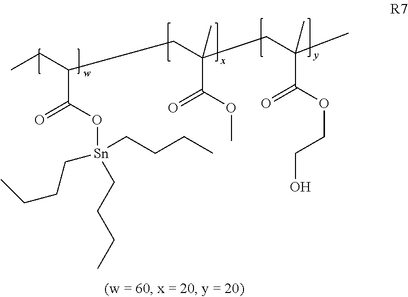

### Synthesis Example 11

27.76 g of dibutyltin maleate (TCI), 2.00 g of methyl methacrylate (Samchun Chemicals), and 146.88 g of diisoamyl ether (DIAE) were added to a 250 mL 2-neck round bottom flask under a nitrogen atmosphere and then, heated to an internal temperature of 115° C.

The subsequent process was carried out in substantially the same manner as in Synthesis Example 4 to obtain Copolymer R8 (Mw=5,000).

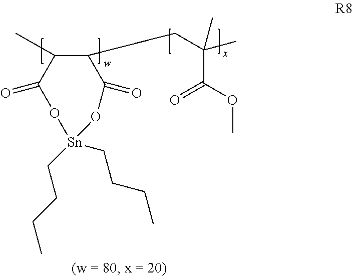

### Synthesis Example 12

21.36 g of trimethyltin styrene (TCI), 2.00 g of methyl methacrylate (MMA, Samchun Chemicals), and 121.07 g of diisoamyl ether (DIAE) were added to a 250 mL 2-neck round bottom flask under a nitrogen atmosphere and then, heated to an internal temperature of 115° C.

The subsequent process was carried out in substantially the same manner as in Synthesis Example 4 to obtain Copolymer R9 (Mw=5,000).

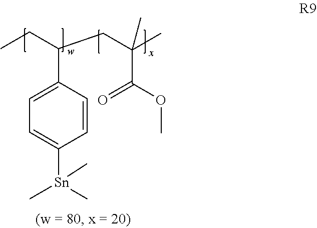

### Synthesis Example 13

30.01 g of tributyltin methacrylate (TCI), 2.00 g of methyl methacrylate (MMA, Samchun Chemicals), and 155.88 g of diisoamyl ether (DIAE) were added to a 250 mL 2-neck round bottom flask under a nitrogen atmosphere and then, heated to an internal temperature of 115° C.

The subsequent process was carried out in substantially the same manner as in Synthesis Example 4 to obtain Copolymer R10 (Mw=5,000).

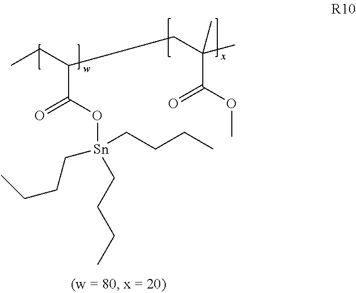

### Synthesis Example 14

34.7 g of dibutyltin maleate (TCI) and 166.43 g of diisoamyl ether (DIAE) were added to a 250 mL 2-neck round bottom flask under a nitrogen atmosphere and then, heated to an internal temperature of 115° C.

The subsequent process was carried out in substantially the same manner as in Synthesis Example 4 to obtain Copolymer R11 (Mw=5,000).

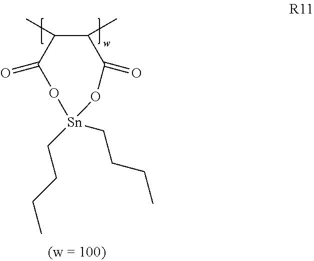

### Synthesis Example 15

26.7 g of trimethyltin styrene (TCI) and 134.42 g of diisoamyl ether (DIAE) were added to a 250 mL 2-neck round bottom flask under a nitrogen atmosphere and then, heated to an internal temperature of 115° C.

The subsequent process was carried out in substantially the same manner as in Synthesis Example 4 to obtain Copolymer R12 (Mw=5,000).

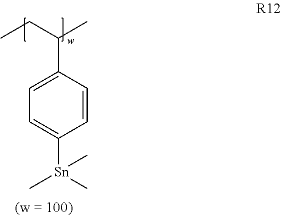

### Synthesis Example 16

37.51 g of tributyltin methacrylate (TCI) and 177.68 g of diisoamyl ether (DIAE) were added to a 250 mL 2-neck round bottom flask under a nitrogen atmosphere and then, heated to an internal temperature of 115° C.

The subsequent process was carried out in substantially the same manner as in Synthesis Example 4 to obtain Copolymer R13 (Mw=5,000).

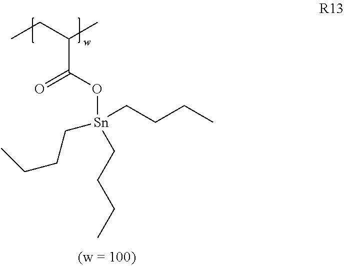

### Synthesis Example 17

Copolymer R14 (Mw=5,000) was obtained in substantially the same manner as in Synthesis Example 4 except that the dibutyltin maleate was not used.

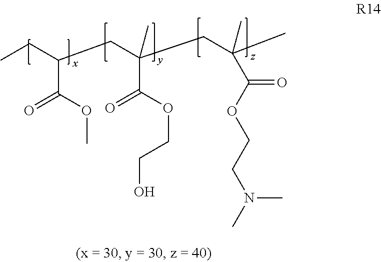

### Synthesis Example 18

10.01 g of methyl methacrylate (Samchun Chemicals), 13.01 g of hydroxy ethyl methacrylate (LG Chem), and 147.37 g of diisoamyl ether (DIAE) were added to a 250 mL 2-neck round bottom flask under a nitrogen atmosphere and then, heated to an internal temperature of 115° C.

The subsequent process was carried out in substantially the same manner as in Synthesis Example 4 to obtain Copolymer R15 (Mw=5,000).

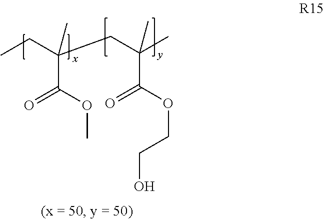

### Synthesis Example 19

13.01 g of hydroxy ethyl methacrylate (LG Chem), 15.72 g of dimethyl aminoethyl methacrylate (Sigma-Aldrich Co., Ltd.), and 132.70 g of diisoamyl ether (DIAE) were added to a 250 mL 2-neck round bottom flask under a nitrogen atmosphere and then, heated to an internal temperature of 115° C.

The subsequent process was carried out in substantially the same manner as in Synthesis Example 4 to obtain Copolymer R16 (Mw=5,000).

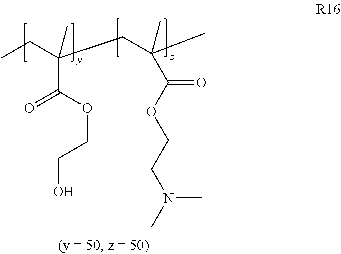

### Synthesis Example 20

10.01 g of methyl methacrylate (Samchun Chemicals), 15.72 g of dimethyl aminoethyl methacrylate (Sigma-Aldrich Co., Ltd.), and 158.19 g of diisoamyl ether (DIAE) were added to a 250 mL 2-neck round bottom flask under a nitrogen atmosphere and then, heated to an internal temperature of 115° C.

The subsequent process was carried out in substantially the same manner as in Synthesis Example 4 to obtain Copolymer R17 (Mw=5,000).

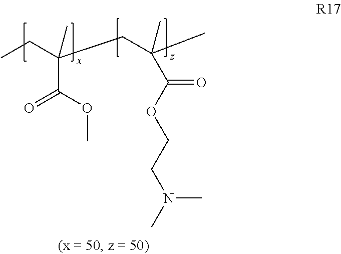

### (Preparation of Semiconductor Photoresist Compositions)

### Examples 1 to 25 and Comparative Examples 1 to 7

The organometallic compounds respectively represented by Chemical Formulas 5a, 6, and 7 according to Synthesis Examples 1 to 3 and respective Polymers R1 to R17 according to Synthesis Examples 4 to 20 in a weight ratio shown in Table 1 were dissolved in propylene glycol methyl ether acetate (PGMEA) at a concentration of 3 wt % and then, filtered with a 0.1 μm PTFE (polytetrafluoroethylene) syringe filter, preparing each semiconductor photoresist composition according to Examples 1 to 25 and Comparative Examples 1 to 7.

TABLE 1

| | Organometallic | (Meth)acrylate- |
|---|---|---|
| | compound | based polymer |
| | (wt %) | (wt %) |
| Comparative | Chemical Formula 5a | — |
| Example 1 | (3.0) | |
| Example 1 | Chemical Formula 5a | R1 |
| | (2.5) | (0.5) |
| Example 2 | Chemical Formula 5a | R1 |
| | (2.0) | (1.0) |
| Example 3 | | R2 |
| | | (1.0) |
| Example 4 | | R3 |
| | | (1.0) |
| Example 5 | | R4 |
| | | (1.0) |
| Example 6 | | R5 |
| | | (1.0) |
| Example 7 | | R6 |
| | | (1.0) |
| Example 8 | | R7 |
| | | (1.0) |
| Example 9 | | R8 |
| | | (1.0) |
| Example 10 | | R9 |
| | | (1.0) |
| Example 11 | | R10 |
| | | (1.0) |
| Example 12 | | R11 |
| | | (1.0) |
| Example 13 | | R12 |
| | | (1.0) |
| Example 14 | | R13 |
| | | (1.0) |
| Comparative | | R14 |
| Example 2 | | (1.0) |
| Comparative | | R15 |
| Example 3 | | (1.0) |
| Comparative | | R16 |
| Example 4 | | (1.0) |
| Comparative | | R17 |
| Example 5 | | (1.0) |
| Comparative | Chemical Formula 6 | — |
| Example 6 | (3.0) | |
| Example 15 | Chemical Formula 6 | R1 |
| | (2.5) | (0.5) |
| Example 16 | Chemical Formula 6 | R1 |
| | (2.0) | (1.0) |
| Example 17 | | R2 |
| | | (1.0) |
| Example 18 | | R3 |
| | | (1.0) |
| Example 19 | | R4 |
| | | (1.0) |
| Comparative | Chemical Formula 7 | — |
| Example 7 | (3.0) | |
| Example 20 | Chemical Formula 7 | R5 |
| | (2.5) | (0.5) |
| Example 21 | Chemical Formula 7 | R1 |
| | (2.5) | (0.5) |
| Example 22 | Chemical Formula 7 | R1 |
| | (2.0) | (1.0) |
| Example 23 | | R2 |
| | | (1.0) |
| Example 24 | | R3 |
| | | (1.0) |
| Example 25 | | R4 |
| | | (1.0) |

### Evaluation: Evaluation of Sensitivity and Line Edge Roughness (LER)

Each of the photoresist compositions according to Examples and Comparative Examples was spin-coated for 30 seconds at 1500 rpm on a 200 mm circular silicon wafer whose surface was deposited with hexamethyldisilazane (HMDS), and baked at 110° C. for 60 seconds. After application, it was baked (post-apply bake, PAB) and then left at room temperature (23±2° C.) for 30 seconds, to prepare a respective coated wafer.

Then, a linear array of 50 circular pads with a diameter of 500 μm was projected onto the wafer coated with the photoresist composition using EUV light (Lawrence Berkeley National Laboratory Micro Exposure Tool, MET). Here, pad exposure time was adjusted to ensure that the EUV light in an increased dose was applied to each pad.

Then, the photoresist and the substrate were baked at 160° C. for 120 seconds on a hot plate after the exposure. The baked film was developed in a PGMEA solvent to form a negative tone image. Finally, the obtained film was baked again at 150° C. for 2 minutes on the hot plate, completing the process.

The remaining photoresist thickness of the exposed pad was measured using an ellipsometer. The remaining thickness for each exposure amount was measured and graphed as a function of the exposure doses to measure the sensitivity. After measuring the LER from the FE-SEM (Field Emission Scanning Electron Microscopy) image, the sensitivity and line edge roughness were evaluated according to the following criteria, and the results are shown in Table 2.

Evaluation criteria for sensitivity
A: less than 50 mJ/cm²
B: greater than or equal to 50 mJ/cm²
   Evaluation criteria for LER
∘: less than or equal to 2 nm
Δ: greater than 2 nm and less than or equal to 5 nm
X: greater than 5 nm

TABLE 2

| | Sensitivity | LER |
|---|---|---|
| Example 1 | A | ◯ |
| Example 2 | A | ◯ |
| Example 3 | A | ◯ |
| Example 4 | A | ◯ |
| Example 5 | A | ◯ |
| Example 6 | A | ◯ |
| Example 7 | A | ◯ |
| Example 8 | A | ◯ |
| Example 9 | A | ◯ |
| Example 10 | A | ◯ |
| Example 11 | A | ◯ |
| Example 12 | A | ◯ |
| Example 13 | A | ◯ |
| Example 14 | A | ◯ |
| Example 15 | A | ◯ |
| Example 16 | A | ◯ |
| Example 17 | A | ◯ |
| Example 18 | A | ◯ |
| Example 19 | A | ◯ |
| Example 20 | A | ◯ |
| Example 21 | A | ◯ |
| Example 22 | A | ◯ |
| Example 23 | A | ◯ |
| Example 24 | A | ◯ |
| Example 25 | A | ◯ |
| Comparative | B | X |
| Example 1 | | |
| Comparative | C | Δ |
| Example 2 | | |
| Comparative | C | Δ |
| Example 3 | | |
| Comparative | C | Δ |
| Example 4 | | |
| Comparative | C | X |
| Example 5 | | |
| Comparative | B | X |
| Example 6 | | |
| Comparative | B | X |
| Example 7 | | |

From the results in Table 2, the patterns formed using the semiconductor photoresist compositions according to Examples 1 to 25 exhibited enhanced (e.g., superior) sensitivity, LER, and resolution characteristics compared to Comparative Examples 1 to 7. These results demonstrate the significant enhancements in performance achieved by the photoresist compositions of the present disclosure. The enhanced sensitivity ensures that the photoresist responds more effectively to EUV exposure, while the improved LER and resolution characteristics contribute to the formation of more precise and reliable patterns. This advancement is for the development of next-generation semiconductor devices, where miniaturization and accuracy are important. The ability to achieve such fine patterns with high fidelity not only enhances the overall performance of semiconductor devices but also supports the trend towards smaller, more powerful, and more efficient electronic components.

As utilized herein, the terms “and/or” and “or” may include any and all combinations of one or more of the associated listed items. The “/” utilized below may be interpreted as “and” or as “or” depending on the situation. In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

It will be further understood that the terms “comprise(s)/comprising”, “include(s)/including,” or “have/has/having,” when utilized in the present disclosure, specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure”.

In the context of the present disclosure and unless otherwise defined, the terms “use,” “using,” and “used” may be considered synonymous with the terms “utilize,” “utilizing,” and “utilized,” respectively.

As utilized herein, the term “about,” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

A pattern forming device, a semiconductor forming device and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hereinbefore, the example embodiments have been described and illustrated, however, it is apparent to a person with ordinary skill in the art that the present disclosure is not limited to the example embodiments as described, and may be variously modified and transformed without departing from the spirit and scope of the disclosure. Accordingly, the modified or transformed embodiments as such may not be understood separately from the technical ideas and aspects of the disclosure, and the modified embodiments are within the scope of the claims of the disclosure. It is further to be understood that the scope of the present disclosure is defined by the appended claims and equivalents thereof rather than the detailed description described above, and all modifications and alterations derived from the claims and their equivalents fall within the scope of the present disclosure.

Reference Numerals

| | |
|---|---|
| 100: substrate | 102: thin film |
| 104: resist underlayer | 106: photoresist film |
| 106a: unexposed region | 106b: exposed region |
| 108: photoresist pattern | 112: organic film pattern |
| 110: patterned mask | 114: thin film pattern |

What is claimed is:

1. A semiconductor photoresist composition, comprising
an organometallic compound;
a (meth)acrylate-based polymer comprising at least one selected from among metals each having a valence of 2 to 6; and
a solvent.

2. The semiconductor photoresist composition as claimed in claim 1, wherein
the (meth)acrylate-based polymer comprises at least one selected from among a structural unit derived from a monomer represented by Chemical Formula 1 and a structural unit derived from a monomer represented by Chemical Formula 2: 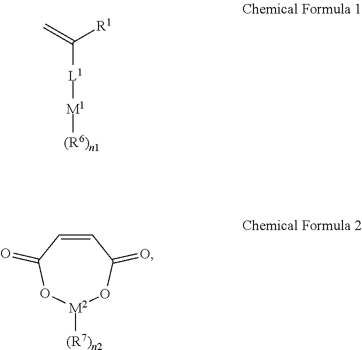
and
wherein, in Chemical Formula 1 and Chemical Formula 2,
R¹ is hydrogen or a substituted or unsubstituted C1 to C10 alkyl group,
M¹ and M² are each independently a metal having a valence of 2 to 6,
L¹ is a single bond, —C(O)O—, a substituted or unsubstituted C1 to C10 alkylene group, a substituted or unsubstituted C6 to C20 arylene group, or a combination thereof,
R⁶ and R⁷ are each independently a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C6 to C20 aryl group, OR^{b}, or OC(═O)R^{c}, R^{b} and R^{c} being each independently a substituted or unsubstituted C1 to C10 alkyl group,
n1 is an integer from 1 to 5, and
n2 is an integer from 0 to 4.

3. The semiconductor photoresist composition as claimed in claim 2, wherein
M¹ is Sn, Sb, or Te,
M² is Sn or Sb,
n1 is an integer from 1 to 3, and
n2 is an integer of 1 or 2.

4. The semiconductor photoresist composition as claimed in claim 2, wherein
M¹ and M² are each Sn,
n1 is an integer of 3, and
n2 is an integer of 2.

5. The semiconductor photoresist composition as claimed in claim 2, wherein
the monomer represented by Chemical Formula 1 and the monomer represented by Chemical Formula 2 are each selected from among monomers listed in Group I:

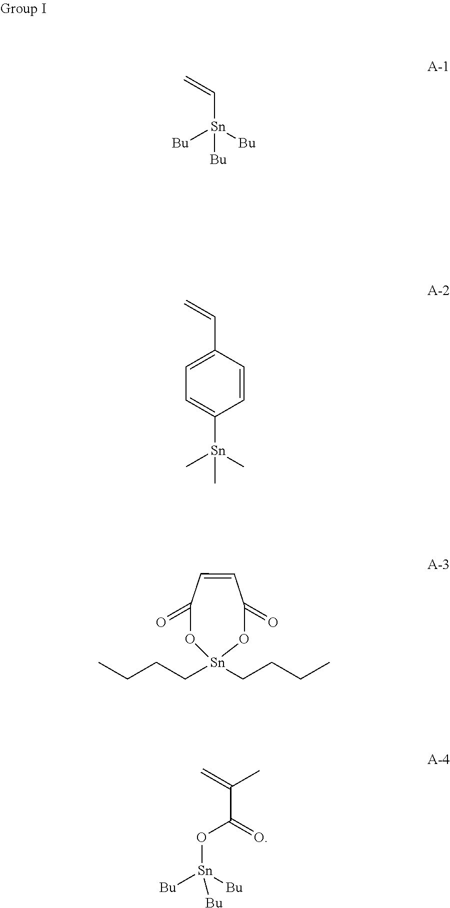

6. The semiconductor photoresist composition as claimed in claim 2, wherein
the (meth)acrylate-based polymer comprises about 50 to about 100 mol % of at least one selected from among the structural unit derived from the monomer represented by Chemical Formula 1 and the structural unit derived from the monomer represented by Chemical Formula 2.

7. The semiconductor photoresist composition as claimed in claim 1, wherein
the (meth)acrylate-based polymer further comprises at least one selected from among a structural unit derived from an alkyl (meth)acrylate monomer, a structural unit derived from a hydroxyl group-containing (meth)acrylate monomer, a structural unit derived from an amino group-containing (meth)acrylate monomer, and a combination thereof.

8. The semiconductor photoresist composition as claimed in claim 1, wherein
the (meth)acrylate-based polymer is in an amount of about 0.001 wt % to about 10 wt % based on 100 wt % of a total weight of the semiconductor photoresist composition.

9. The semiconductor photoresist composition as claimed in claim 1, wherein
the organometallic compound is in an amount of about 0.5 wt % to about 30 wt % based on 100 wt % of a total weight of the semiconductor photoresist composition.

10. The semiconductor photoresist composition as claimed in claim 1, wherein
the semiconductor photoresist composition further comprises an additive of a surfactant, a crosslinking agent, a leveling agent, an organic acid, a quencher, or a combination thereof.

11. The semiconductor photoresist composition as claimed in claim 1, wherein
the organometallic compound comprises at least one of an organic oxy group or an organic carbonyloxy group.

12. The semiconductor photoresist composition as claimed in claim 1, wherein
the organometallic compound is represented by Chemical Formula 3: 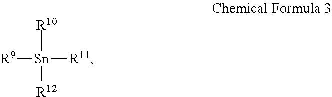
and
wherein, in Chemical Formula 3,
R⁹ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C6 to C30 arylalkyl group,
R¹⁰ to R¹² are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)R^{j}, wherein R^{h}, Rⁱ, and R^{j} are each independently hydrogen, a substituted or unsubstituted C1 to C20 alkyl group, a C2 to C20 alkenyl group, a substituted or unsubstituted C2 to C20 alkynyl group, a substituted or unsubstituted C6 to C30 aryl group, or a combination thereof), an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from among R¹⁰ to R¹² is selected from among an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

13. The semiconductor photoresist composition as claimed in claim 12, wherein
at least one selected from among R¹⁰ to R¹² is selected from among an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

14. The semiconductor photoresist composition as claimed in claim 13, wherein
R⁹ is a substituted or unsubstituted C1 to C8 alkyl group, a substituted or unsubstituted C3 to C8 cycloalkyl group, a substituted or unsubstituted C2 to C8 aliphatic unsaturated organic group comprising one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof,
R^{b} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

15. The semiconductor photoresist composition as claimed in claim 1, wherein
the organometallic compound is represented by Chemical Formula 4 or Chemical Formula 5: 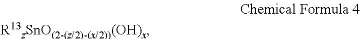
in Chemical Formula 4,
R¹³ being a C1 to C31 hydrocarbyl group, 0<z≤2, and 0<(z+x)≤4; and 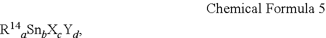
in Chemical Formula 5,
R¹⁴ being a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X being sulfur(S), selenium (Se), or tellurium (Te),
Y being —OR^{m} or —OC(═O)Rⁿ,
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d being each independently an integer of 1 to 20.

16. A method, comprising
forming an etching-objective layer on a substrate;
coating the semiconductor photoresist composition as claimed in claim 1 on the etching-objective layer to form a photoresist film;
patterning the photoresist film to form a photoresist pattern; and
etching the etching-objective layer utilizing the photoresist pattern as an etching mask,
wherein the method is a method of forming patterns.
